(19) United States
(12) Patent Application Publication
(10) Pub. No.: US 2009/0026586 A1
(43) Pub. Date: Jan. 29, 2009

(54) Superjunction Device Having Oxide Lined Trenches and Method for Manufacturing a Superjunction Device Having Oxide Lined Trenches

(75) Inventor: Samuel Anderson, Tempe, AZ (US)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: ICEMOS TECHNOLOGY CORPORATION, Tempe, AZ (US)

(21) Appl. No.: 10/596,720

(22) PCT Filed: Apr. 21, 2006
(86) PCT No.: PCT/US06/15310

§ 371 Date: Jun. 22, 2006

Related U.S. Application Data
(60) Provisional application No. 60/673,935, filed on Apr. 22, 2005.

(51) Int. Cl. H01L 29/06; H01L 21/22

(52) U.S. Cl. 257/623; 438/542; 257/E29.002; 257/E21.135

(57) ABSTRACT

A method of manufacturing a semiconductor device includes providing semiconductor substrate having trenches and mesas. At least one mesa has first and second sidewalls. The method includes doping with a dopant of a second conductivity the first sidewall of the mesa, and doping with a dopant of a second conductivity the second sidewall of the mesa. A dopant of the first conductivity is then used to dope the first sidewall of the mesa, and the dopant of the first conductivity is used to dope the second sidewall of the at least one mesa. At least the trenches adjacent to the at least one mesa are then lined with an oxide material and are then filled with one of a semi-insulating material and an insulating material.

### BACKGROUND OF THE INVENTION

The present invention relates to a semiconductor device and a method for manufacturing a semiconductor device, and more particularly, to a superjunction device having oxide lined trenches and a method for manufacturing a superjunction device having oxide lined trenches.

Since the invention of superjunction devices by Dr. Xingbi Chen, as disclosed in U.S. Pat. No. 5,216,275, there have been many attempts to expand and improve on the superjunction effect of his invention. U.S. Patents Nos. 6,410,958, 6,300,171 and 6,307,246 are examples of such efforts and are incorporated herein by reference.

U.S. Pat. No. 6,410,958 (“Usui, et al.”.) relates to an edge termination structure and a drift region for a semiconductor component. A semiconductor body of one conductivity type has an edge area with a plurality of regions of the other conductivity type embedded in at least two mutually different planes. Underneath the active zone of the semiconductor component, the drift regions are connected using the underlying substrate.

U.S. Pat. No. 6,307,246 (“Nitta, et al.”) discloses a semiconductor component having a high-voltage sustaining edge structure in which a multiplicity of parallel-connected individual components are disposed in a multiplicity of cells of a cell array. In an edge region, the semiconductor component has cells with shaded source zone regions. During commutation of the power semiconductor component, the shaded source zone regions suppress the switching “on” of a parasitic bipolar transistor caused by a disproportionately large reverse flow current density. Moreover, an edge structure having shaded source zone regions can be produced very easily in technological terms that are discussed in the Nitta, et al. patent. It clarifies the effects of parameters and enables the mass production of a superjunction semiconductor device which has a drift layer comprised of a parallel pn layer that conducts electricity in the “on” state and is depleted in the “off” state. The net quantity of active impurities in the n-type drift regions is within the range of 100% to 150% of the net quantity of active impurities in the p-type partition regions. In addition, the width of either one of the n-type drift regions and the p-type partition regions is within the range of between 94% and 106% of the width of the other regions.

U.S. Pat. No. 6,300,171 (“Frisina”) discloses a method for manufacturing an edge structure for a high voltage semiconductor device, including a first step of forming a first semiconductor layer of a first conductivity type, a second step of forming a first mask over the top surface of the first semiconductor layer, a third step of removing portions of the first mask in order to form at least one opening in the first mask, a fourth step of introducing dopant of a second conductivity type in the first semiconductor layer through the at least one opening, a fifth step of completely removing the first mask and of forming a second semiconductor layer of the first conductivity type over the first semiconductor layer, and a sixth step of diffusing the dopant implanted in the first semiconductor layer in order to form a doped region of the second conductivity type in the first and second semiconductor layers. The second step up to the sixth step are repeated at least one time in order to form a final edge structure including a number of superimposed semiconductor layers of the first conductivity type and at least two columns of doped regions of the second conductivity type, the columns being inserted in the number of superimposed semiconductor layers and formed by superimposition of the doped regions subsequently implanted through the mask openings, the columns near the high voltage semiconductor device being deeper than the columns farther from the high voltage semiconductor device.

It is desirable to provide a superjunction device having an oxide liner and a method for manufacturing a superjunction device having oxide lined trenches. It is also desirable to provide a method for manufacturing such a superjunction device utilizing known techniques such as plasma etching, reactive ion etching (RIE), sputter etching, vapor phase etching, chemical etching, deep RIE or the like.

### BRIEF SUMMARY OF THE INVENTION

Briefly stated, an embodiment of the present invention comprises a method of manufacturing a semiconductor device. To begin the process, a semiconductor substrate having first and second main surfaces opposite to each other is provided. The semiconductor substrate has a heavily doped region of a first conductivity type at the second main surface and has a lightly doped region of the first conductivity type at the first main surface. A plurality of trenches and a plurality of mesas are provided in the semiconductor substrate with each mesa having an adjoining trench and a first extending portion extending from the first main surface toward the heavily doped region to a first depth position. At least one mesa has a first sidewall surface and a second sidewall surface. Each of the plurality of trenches has a bottom. The method includes doping with a dopant of a second conductivity type the first sidewall surface of the at least one mesa to form a first doped region of the second conductivity type. The method also includes doping with a dopant of the second conductivity type the second sidewall surface of the at least one mesa to form a third doped region of the second conductivity type. The method includes doping with a dopant of the first conductivity type the first sidewall surface of the at least one mesa to provide a second doped region of the first conductivity type at the first sidewall, and doping with the dopant of the first conductivity type the second sidewall of the at least one mesa to provide a fourth doped region of the first conductivity type at the second sidewall. At least the trenches adjacent to the at least one mesa are then lined with an oxide material and are then filled with one of a semi-insulating material and an insulating material.

In another aspect, an embodiment of the present invention comprises a method of manufacturing a semiconductor device. To begin the process, a semiconductor substrate having first and second main surfaces opposite to each other is provided. The semiconductor substrate has a heavily doped region of a first conductivity type at the second main surface and has a lightly doped region of the first conductivity type at the first main surface. A plurality of trenches and a plurality of mesas are provided with each mesa having an adjoining trench and a first extending portion extending from the first main surface toward the heavily doped region to a first depth position. At least one mesa has a first sidewall surface and a second sidewall surface. Each of the plurality of trenches has a bottom. The method includes doping with a dopant of a first conductivity type the first sidewall surface of the at least one mesa to form a first doped region of the first conductivity type. The method also includes doping with a dopant of the first conductivity type the second sidewall surface of the at least one mesa to form a second doped region of the first conductivity type. The method includes doping with a dopant of the second conductivity type into the first sidewall surface of the at least one mesa to provide a second doped region of the first conductivity type at the first sidewall, and doping with the dopant of the second conductivity type the second sidewall of the at least one mesa. At least the trenches adjacent to the at least one mesa are then lined with an oxide material and are then filled with one of a semi-insulating material and an insulating material.

Other embodiments of present invention comprise the semiconductors formed by the above methods.

### BRIEF DESCRIPTION OF SEVERAL VIEWS OF THE DRAWINGS

The foregoing summary, as well as the following detailed description of preferred embodiments of the invention, will be better understood when read in conjunction with the appended drawings. For purposes of illustrating the invention, there are shown in the drawings embodiments which are presently preferred. It should be understood, however, that the invention is not limited to the precise arrangements and instrumentalities shown.

FIG. 1 is a partial sectional elevational view of an n type semiconductor substrate having an oxide liner in accordance with a first preferred embodiment of the present invention;

FIG. 2 is a partial sectional elevational view of an n type semiconductor substrate;

FIG. 3 is a partial sectional elevational view of the semiconductor substrate of FIG. 2 after an etch step, implanting a p conductivity dopant at first and second predetermined angles of implant and diffusing the implanted ions;

FIG. 4 is a partial sectional elevational view of the semiconductor substrate of FIG. 3 after implanting an n conductivity dopant at the first and second predetermined angles of implant and diffusing the implanted ions;

FIG. 5 is a partial sectional elevational view of the semiconductor substrate of FIG. 4 after lining with an oxide material, refilling with a semi-insulative material and planarizing;

FIG. 6 is a partial sectional elevational view of the semiconductor substrate of FIG. 5 showing the device prepared for formation of an active device;

FIG. 7 is a partial sectional elevational view of a cell description of a planar metal-oxide semiconductor field effect transistor (MOSFET) n type structure using a standard planar process in accordance with the first preferred embodiment;

FIG. 8 is a partial sectional elevational view of a cell description of a planar MOSFET n type structure using a standard planar process in accordance with an alternate of the first preferred embodiment;

FIG. 9 is a partial sectional elevational view of an n type semiconductor substrate having an oxide liner and a buffer layer in accordance with a second preferred embodiment of the present invention;

FIG. 10 is a partial sectional elevational view of an n type semiconductor substrate having an oxide liner in accordance with a third preferred embodiment of the present invention;

FIG. 11 is a partial sectional elevational view of an n type semiconductor substrate;

FIG. 12 is a partial sectional elevational view of the semiconductor substrate of FIG. 11 after an etch step, implanting an n conductivity dopant at first and second predetermined angles of implant and diffusing the implanted ions;

FIG. 13 is a partial sectional elevational view of the semiconductor substrate of FIG. 12 after lining with an oxide material and filling with undoped polysilicon;

FIG. 14 is a partial sectional elevational view of the semiconductor substrate of FIG. 13 after refilling with undoped polysilicon and planarizing;

FIG. 15 is a partial sectional elevational view of the semiconductor substrate of FIG. 14 showing the device prepared for formation of an active device;

FIG. 16 is a partial sectional elevational view of a cell description of a planar MOSFET n type structure using a standard planar process in accordance with the third preferred embodiment; and

FIG. 17 is a partial sectional elevational view of an n type semiconductor substrate having an oxide liner and a buffer layer in accordance with a fourth preferred embodiment of the present invention.

### DETAILED DESCRIPTION OF THE INVENTION

Certain terminology is used in the following description for convenience only and is not limiting. The words “right”, “left”, “lower”, and “upper” designate directions in the drawing to which reference is made. The words “inwardly” and “outwardly” refer direction toward and away from, respectively, the geometric center of the object described and designated parts thereof. The terminology includes the words above specifically mentioned, derivatives thereof and words of similar import. Additionally, the word “a”, as used in the claims and in the corresponding portions of the specification, means “at least one.”

Although any particular embodiment of the present invention may refer to a particular conductivity (e.g., p-type or n-type), it will be readily understood by those skilled in the art that p-type conductivity can be switched with n-type conductivity and vice versa and the device will still be functionally correct (i.e., a first or second conductivity type). Therefore, where used herein, the reference to n-type may be interchangeable with p-type and reference to p-type may be interchangeable with n-type.

Furthermore, n+ and p+ refer to heavily doped n and p regions, respectively; n++ and p++ refer to very heavily doped n and p regions, respectively; n− and p− refer to lightly doped n and p regions, respectively; and n−− and p−− refer to very lightly doped n and p regions, respectively. However, such relative doping terms should not be construed as limiting.

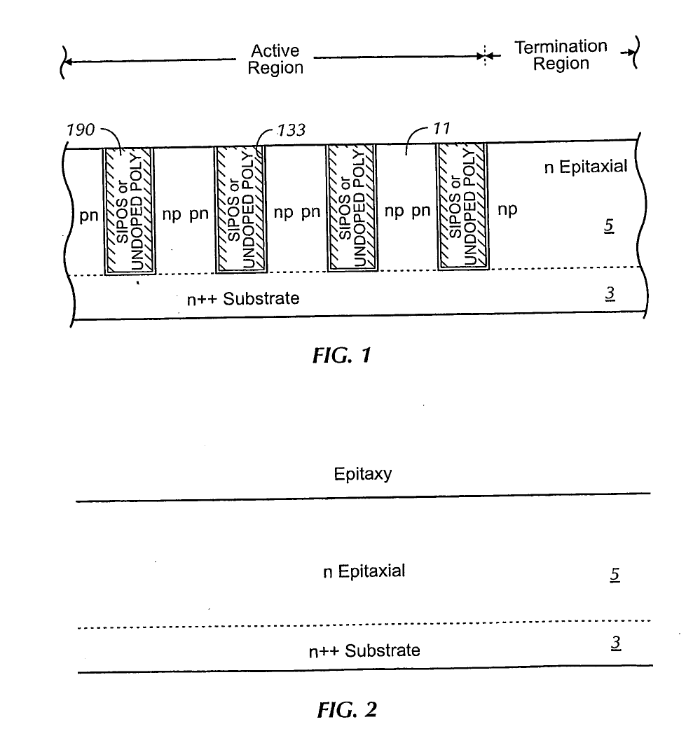

FIGS. 1-6 generally show a process for manufacturing an n type structure in accordance with a first preferred embodiment of the present invention.

Referring to FIG. 2, there is shown a partial elevational view of a semiconductor wafer that includes an n⁺⁺ substrate 3 and an n epitaxial layer 5. As used herein, reference to conductivity will be limited to the embodiment described. However, those skilled in the art know that P-type conductivity can be switched with n-type conductivity and the device would still be functionally correct (i.e., a first or a second conductivity type). Therefore, where used herein, the reference to n or p can also mean that either n and p or p and n can be substituted. Metal oxide semiconductor field effect transistor (MOSFET)-gated devices such as insulated gate bipolar transistors (IGBTs) can be fabricated in an epitaxial wafer with an n-type epitaxial layer over a p⁺ substrate (or visa versa).

FIG. 1 demonstrates the steps necessary to form a partially manufactured superjunction device in accordance with an embodiment of the present invention.

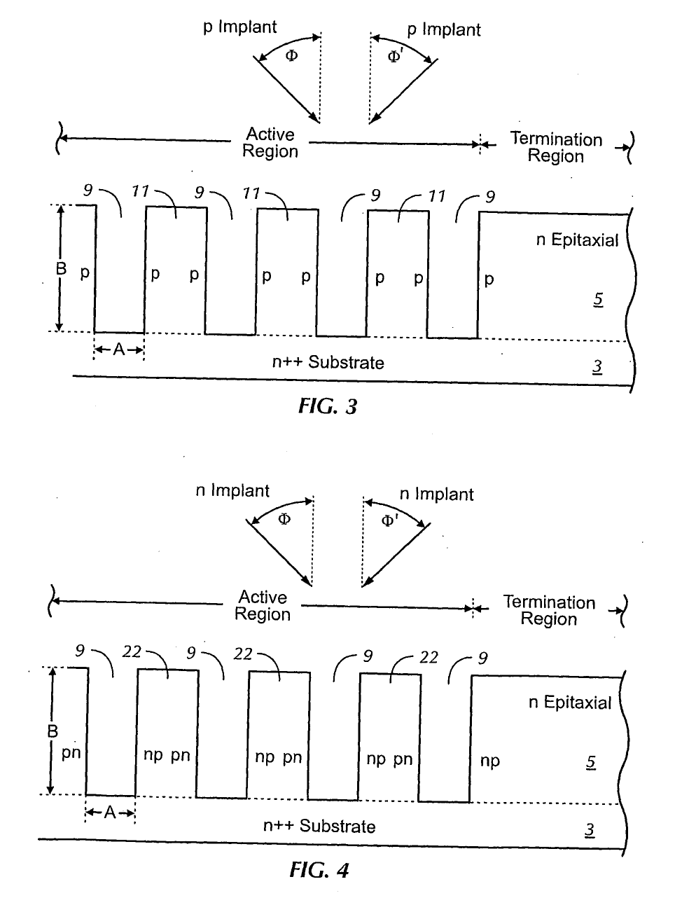

Referring to FIG. 3, using techniques known in the art, the epitaxial layer 5 is etched to touch or to approach an interface between the substrate 3 and the epitaxial layer 5. The etch process creates trenches 9 and mesas 11. The mesas 11, which are “device mesas,” will be used to form the voltage sustaining layer for each transistor or active device cell manufactured by the process. The mesas 11 are referred to as device mesas because the mesas 11 are in an active region, as opposed to a surrounding termination or edge termination region. The active region is the area on which semiconductor devices will be formed, and the termination region is an area which provides insulation between cells of active devices.

The separation of the mesas 11, i.e., the width A of the trenches 9, and the depth B of the trenches 9 is used to determine an implantation angle Φ, Φ′ (i.e., a first or second angle of implant Φ, Φ′) of ion implants that are to be performed and discussed later. For the same reason, the width A between the mesas 11 and the edge termination region is also approximately the same distance. Though not shown clearly, in some embodiments the trenches 9 are preferably slightly wider at their tops by about 1%-10% than at their bottoms to facilitate the trench fill process when the trenches 9, for example, are to be filled with grown oxide. Consequently, the mesas 11, in embodiments with trenches 9 having wider tops, have a first sidewall surface with a predetermined inclination maintained relative to the first main surface and a second sidewall surface with a predetermined inclination maintained relative to the first main surface. The inclination of the first sidewall surface is about the same as the inclination of the second sidewall surface depending on tolerances of the etching process.

In other embodiments, it is desirable to have the sidewalls of the mesas 11 as vertical as possible (i.e., 0° inclination angle). While the first trenches 9 extend from the first main surface of the epitaxial layer 5 toward the substrate (heavily doped region) 3 to the first depth position by depth B, the first trenches 9 do not necessarily extend all the way to the substrate (heavily doped region) 3.

Preferably, the etching is performed by utilizing a known technique such as plasma etching, reactive ion etching (RIE), sputter etching, vapor phase etching, chemical etching, deep RIE or the like. Utilizing deep RIE, trenches 9 can be formed having depths B of about 40 to 300 micrometers or microns (μm) or even deeper. Deep RIE technology permits deeper trenches 9 with much straighter sidewalls. Furthermore, forming deeper trenches 9 that have straighter sidewalls than conventionally etched or formed trenches 9, in addition to other steps in the process, results in a final superjunction device with enhanced avalanche breakdown voltage (V_{b}) characteristics as compared to conventional semiconductor-transistor devices (i.e., the avalanche breakdown voltage (V_{b}) can be increased to about 200 to 1200 Volts or more).

The sidewalls of each trench 9 may be smoothed, if needed, using, for example, one or more of the following process steps: (i) an isotropic plasma etch may be used to remove a thin layer of silicon (typically 100-1000 Angstroms) from the trench surfaces or (ii) a sacrificial silicon dioxide layer may be grown on the surfaces of the trench and then removed using an etch such as a buffered oxide etch or a diluted hydrofluoric (HF) acid etch. The use of either or both of these techniques can produce smooth trench surfaces with rounded corners while removing residual stress and unwanted contaminates. However, in the embodiments where it is desirable to have vertical sidewalls and square comers, an anisotropic etch process will be used instead of the isotropic etch process discussed above. Anisotropic etching, in contrast to isotropic etching, generally means different etch rates in different directions in the material being etched.

Many geometrical arrangements of trenches 9 and mesas 11 (i.e., in plan view) are also contemplated without departing from the invention.

Referring to FIG. 3, at a slight angel Φ (i.e., a first predetermined angle of implant Φ), without benefits of a masking step, the mesas 11 are implanted with a p dopant such as boron (B) (i.e., a dopant having a second conductivity or p conductivity) on one side at a high energy level in the range of about 40 Kilo-electron-volts (KeV) to several Mega-eV. Preferably, the energy level is in the range of about 200 KeV to 1 MeV, but it should be recognized that the energy level should be selected to sufficiently implant the dopant. The first predetermined angle of implant Φ, as represented by thick arrows, is determined by the width A between the mesas 11 and the depth B of the trenches 9 and can be between about 2° and 12° from vertical and is preferably about 4°. The use of the width A and depth B to determine the first predetermined angle of implant Φ ensures that only the sidewalls of the trenches 9 and not the bottoms of the trenches 9 in the active region are implanted. Consequently, a dopant of the second conductivity type is implanted, at a first predetermined angle of implant Φ, into at least one preselected mesa 11 to form at the sidewall surface of the one trench 9 a first doped region of the second conductivity type having a doping concentration lower than that of the heavily doped region. Other doping techniques may be utilized.

The opposite sides of the mesas 11 are implanted with boron B at a second predetermined angle of implant Φ′, as represented by thick arrows. Similar to the first predetermined angle of implant Φ, the second predetermined angle of implant Φ′ is determined by the width A between the mesas 11 and the depth B of the trenches 9 and can be between about −2° and −12° from vertical and preferably at about −4°. The use of the width A and depth B to determine the second predetermined angle of implant Φ′ ensures that only the sidewalls of the trenches 9 and not the bottoms of the trenches 9 in the active region are implanted. Consequently, a dopant of the second conductivity type is implanted, at a second predetermined angle of implant ′, into at least one preselected mesa 11 to form at the sidewall surface of the one trench 9 a second doped region of the second conductivity type having a doping concentration lower than that of the heavily doped region. Other doping techniques may be utilized.

Optionally, following implanting the second p type implant (FIG. 3), a drive in step (i.e., a diffusion) is performed at a temperature of up to about 1200° Celsius for up to about 24 hours so that the mesas 11 are converted to p-p columns 22 (FIG. 4). It should be recognized that the temperature and the time the temperature is maintained are selected to sufficiently drive in the implanted dopant.

As shown in FIG. 4, second implant is then performed with an n type dopant such as phosphorous (P) or arsenic (As). The n type implant is performed at the first predetermined angle of implant and at an energy level of about 30 KeV to 1 MeV. Preferably, the energy level is in the range of about 40 to 300 KeV, but it should be recognized that the energy level should be selected to sufficiently implant the dopant. In FIG. 4, opposite sides of the p-p columns 22 are also implanted with the n type dopant at the second predetermined angle of implant Φ′. Other doping techniques may be utilized.

Optionally, following the second n type implant, a drive in step (i.e., diffusion) is performed at a temperature of up to about 1200° Celsius for up to about 24 hours resulting in the p-p pillars 22 being converted to np-pn columns 27 (FIG. 5) and the right side termination n and p region 31 as shown in FIG. 5.

The trenches 9 are then lined or coated with a thin layer of an oxide dielectric material forming an oxide liner 133 on the sides of the np-pn columns 27 and the bottoms of the trenches 9. The lining of the trenches is performed, in the present embodiment using a technique known as low pressure (LP) chemical vapor deposition (CVD) Tetraethylorthosilicate (TEOS) or simply “LPTEOS.” Alternatively, a spun-on-glass (SOG) technique or any other suitable technique may be used for may be used to line the trenches 9 with the oxide liner 133. Preferably, the oxide liner 133 is about 100 Angstroms (Å) to 10,000 Å thick (1 μm=10,000 Å). The oxide liner 133 reduces charges on the surface of the silicon in the trenches 9 because the oxide will “consume” the charges on the surface of the walls of the trenches 9.

The trenches 9 are then refilled (filled) with a semi-insulating material or doped or undoped polysilicon (poly) 190. The semi-insulating material can be semi-insulating polycrystalline silicon (SIPOS). Preferably, the trenches 9 are refilled with SIPOS 190. The amount of oxygen content in the SIPOS is selectively chosen to be between 2% and 80% to improve the electrical characteristics of the active region. Increasing the amount of oxygen content is desirable for electrical characteristics, but varying the oxygen content also results in altered material properties. Higher oxygen content SIPOS will thermally expand and contract differently than the surrounding silicon which may lead to undesirable fracturing or cracking especially near the interface of differing materials. Accordingly, the oxygen content of the SIPOS is optimally selected to achieve the most desirable electrical characteristics without an undesirable impact on mechanical properties.

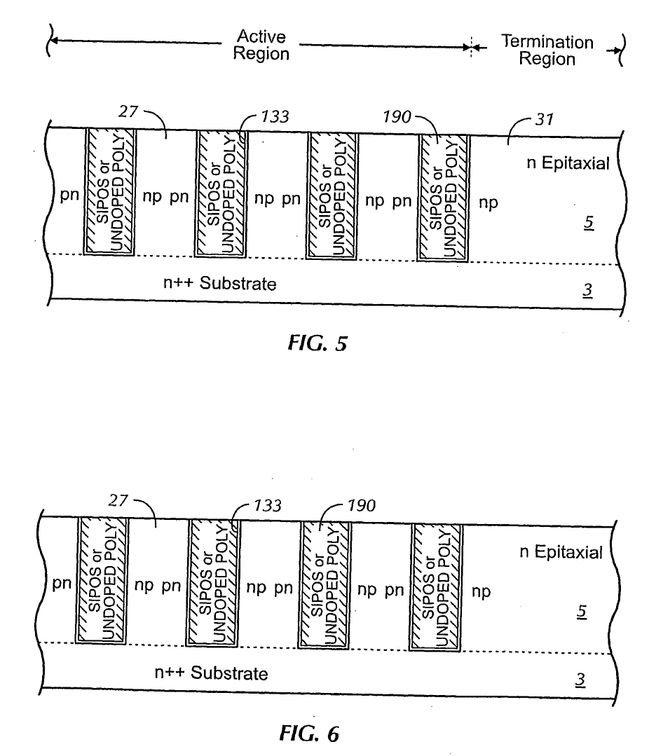

FIG. 6 shows that after the refill, the device is planarized preferably using chemical mechanical polishing (CMP) or other techniques known in the art. The n/p columns 27 are exposed in order to create the device features for a transistor to be formed thereon. The amount of planarization is about 0.6-3.2 μm. The amount of planarization is chosen so as to sufficiently expose the n/p columns 27, but to not open any internal voids in the fill material 190 that may have occurred during the fill process. Preferably, the planarization is about 1.0-1.5 μm. Optionally, termination rings such as p type termination rings can then be added in the termination region 31.

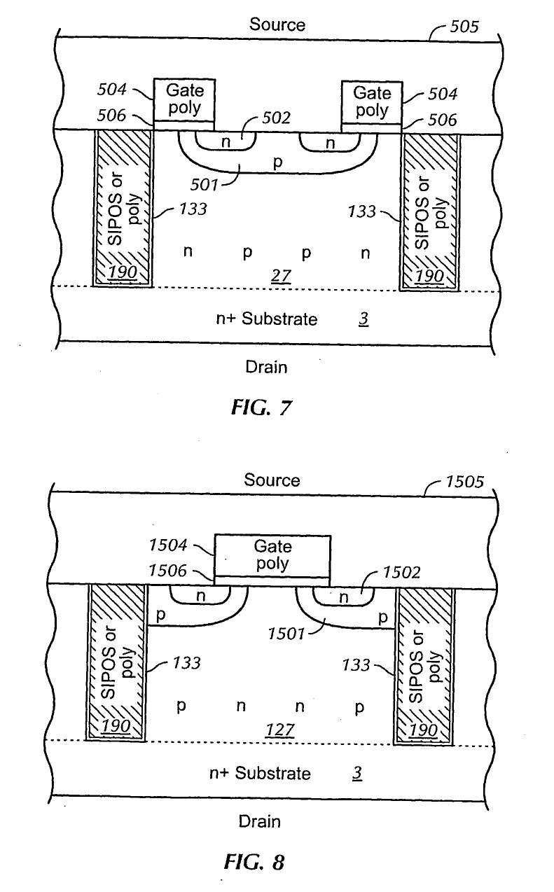

FIGS. 7 and 8 are partial sectional elevational views of a cell descriptions (i.e., configurations of individual devices or cells of a single-cell or multi-cell chip) of planar metal-oxide semiconductor field effect transistor (MOSFET) n type structures using a standard planar process in accordance with the first preferred embodiment.

FIG. 7 shows an np-pn mesa device in accordance with the first preferred embodiment having an np-pn column 27 that is isolated from other neighboring cells by the oxide liner 133 and the SIPOS or poly refill 190. The substrate 3 functions as a drain and the np-pn column 27 is disposed thereon. The device also includes a source region 505. The source region 505 includes a p region 501 in which there are formed n source connector regions 502. Oxide layers 506 separates a pair of gate poly regions 504 from the n source connectors 502 and the p region 501.

FIG. 8 shows an alternate of the first preferred embodiment with a pn-np mesa device in which is used in the n type planar MOS structure. The device has a pn-np column 127 that is isolated from other neighboring cells by the oxide liner 133 and the SIPOS or poly refill 190. The substrate 3 functions as a drain and the pn-np column 1.27 is disposed thereon. The device also includes a source region 1505. The source region 1505 includes a p region 1501 in which there is formed n source connector region 1502. An oxide layer 1506 separates a gate poly region 1504 from the n source connector 1502 and the p region 1501.

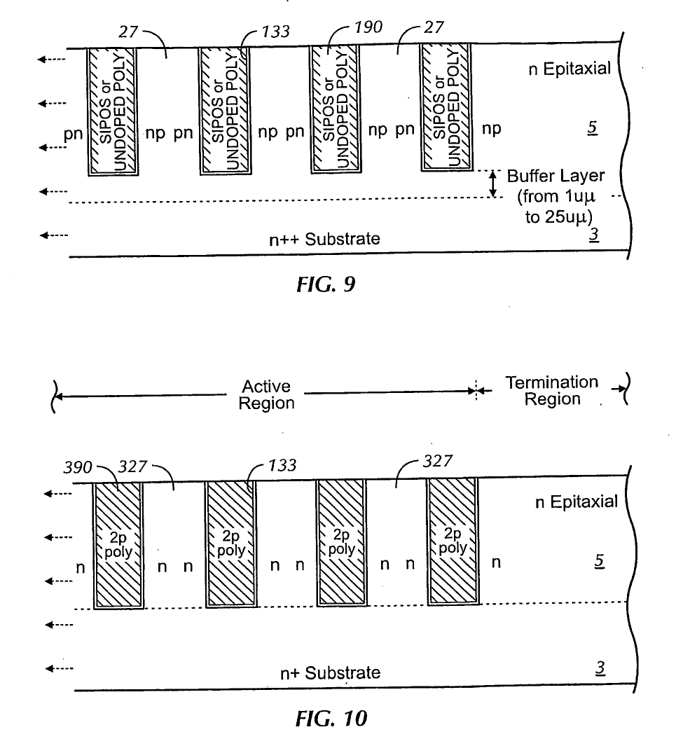

FIG. 9 shows a semiconductor device having an oxide liner 133 in accordance with a second preferred embodiment of the present invention. The second preferred embodiment is similar to the first preferred embodiment except that the trenches 9 (see e.g., FIG. 3) do not extend all the way to the interface between the epitaxial layer 5 and the n⁺⁺ substrate 3. Instead, there is a buffer layer on the order of about 1 μm to 25 μm from the bottoms of the trenches 9 to the interface between the epitaxial layer 5 and the n⁺⁺ substrate 3.

The mesas 11 (FIG. 3) and/or columns 27 (FIG. 9) are shown having a width that is wider than mesas of conventional devices and wider than the trenches 9 (FIG. 3), although the preferred embodiments may be suitable for devices with mesas and/or columns that have a width which is the same as or is narrower than conventional mesas and/or columns. The width of the mesas and/or columns should not be construed as limiting.

FIGS. 10-15 generally show a process for manufacturing an n type structure in accordance with a third preferred embodiment of the present invention.

FIG. 10 shows the third preferred embodiment of an n type structure that includes nn columns 327 that are separated by a double p (2p) doped polysilicon refill 390. FIG. 10 also shows the steps for forming a semiconductor device in accordance with the third preferred embodiment.

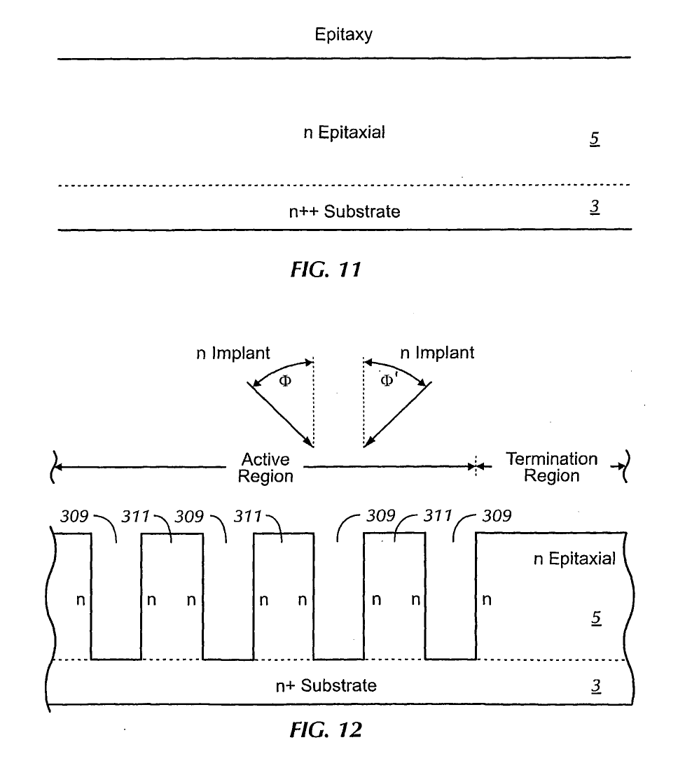

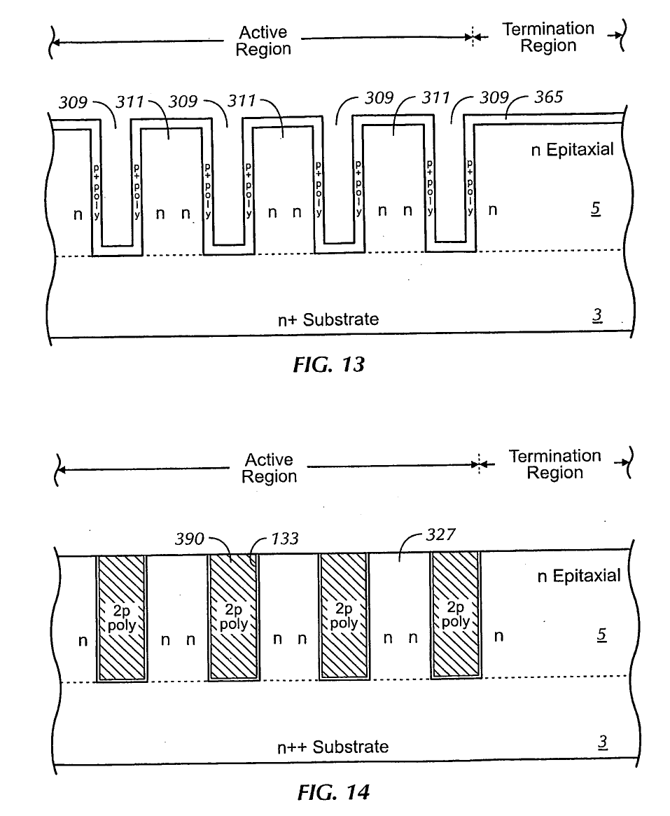

FIG. 11 shows that, similar to the first preferred embodiment, the process begins with an n⁺⁺ substrate 3 having an n type epitaxial layer 5 thereon. An etch formed in n epitaxial layer 5 that approaches the n⁺⁺ substrate 3 to form n mesas 311 that are separated by trenches 309 as shown in FIG. 12. Thereafter, n type dopant is implanted at a first predetermined angle of implant Φ into one side of the mesas 311 and then into the other side of the mesas 311 are implanted with the n type dopant at the second predetermined angle of implant Φ′. Following the n type implants, a drive in step (i.e., diffusion) is performed at a temperature of up to about 1200° Celsius for up to about 24 hours resulting in the n mesas 311 (FIG. 13) being converted to n pillars 327 (FIG. 14).

FIGS. 13 and 14 show that the trenches 309 are filled with a thin layer of oxide material forming an oxide liner 133 on the sides of the n-n pillars 327 and the bottoms of the trenches 309. The oxide liner 133 is preferably formed by LPCVD TEOS. Preferably, the oxide liner 133 is about 100 Å to 10,000 Å. The trenches 309 are then filled with a thin layer of undoped polysilicon 390 on the sides of the n-n pillars 327 and the bottoms of the trenches 309 over the oxide liner 133. Preferably, the undoped polysilicon layer 365 is about 100 Å to 10,000 Å.

Following the lining of the bottoms of the trenches 309 and the sidewalls of n-n pillars 327, a p type dopant is implanted at the first predetermined angle of implant Φ (similar to FIG. 4) following which the other side of the n-n pillar 327 are implanted with a p type dopant at the second predetermined angle of implant Φ′. Thereafter, an undoped polysilicon refill is performed resulting in a 2p polyfill 390 (FIG. 14), and a planarization process is performed. Additionally, a diffusion may optionally be performed before the planarization process is performed. Finally, the device surface can be cleaned and p body implant and cell creation are performed as shown in FIG. 15.

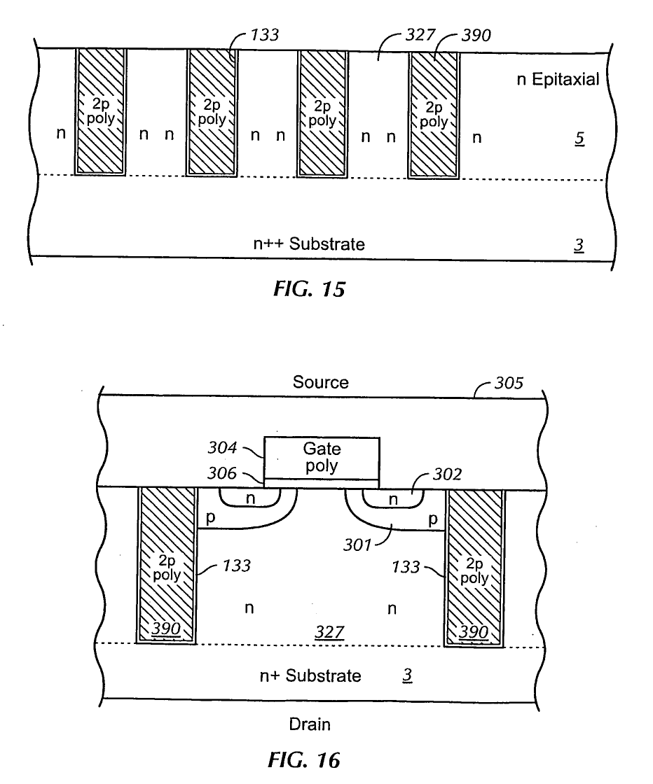

FIG. 16 shows a cellular structure of a device in accordance with the third preferred embodiment having an n pillar 327 that is isolated from other neighboring cells by the oxide liner 133 and 2p poly refill 390. The device includes an n-n pillar 327 mounted on the substrate 3, which is a drain, and the active portion of the device is isolated from the other neighboring cells by the oxide liner 133 and 2p poly region 390. The device also includes a source region 305. The source region 305 includes a p region 301 in which there is formed n source connector region 302. An oxide layer 306 separates a gate poly region 304 from the n source connector 302 and the p region 301.

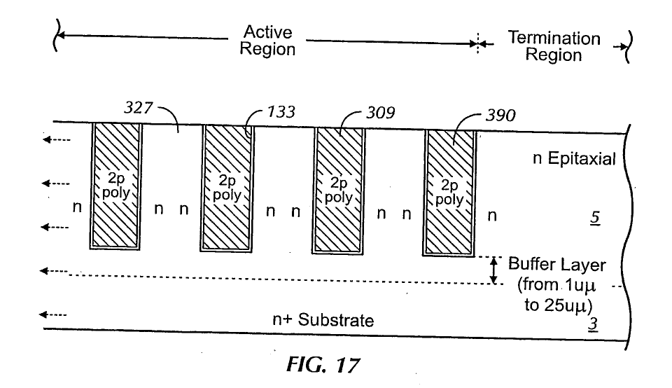

FIG. 17 shows a semiconductor device having an oxide liner 133 in accordance with a fourth preferred embodiment of the present invention. The fourth preferred embodiment is similar to the third preferred embodiment except that the trenches 309 do not extend all the way to the interface between the epitaxial layer 5 and the n⁺⁺ substrate 3. Instead, there is a buffer layer on the order of about 1 μm to 25 μm from the bottoms of the trenches 309 to the interface between the epitaxial layer 5 and the n⁺⁺ substrate 3.

As mentioned above, the processes are versatile as the n columns and p columns can be exchanged. For the manufacture of p-channel, devices the substrate is p⁺ and for an n-channel devices the substrate is n⁺. The refill material can be doped or undoped oxide, semi-insulating material (such as SIPOS), doped or undoped polysilicon (poly), nitride or a combination of materials. The different embodiments can be use to make MOSFETs and Schottky diodes and similar devices.

Finally the edge termination regions may include either floating rings or a field plate termination without departing from the invention.

From the foregoing, it can be seen that embodiments the present invention are directed to a superjunction device having oxide lined trenches and method for manufacturing a superjunction device having an oxide lined trenches. It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

I claim:

1. A method of manufacturing a semiconductor device comprising:
providing a semiconductor substrate having first and second main surfaces opposite to each other, the semiconductor substrate having a heavily doped region of a first conductivity type at the second main surface and having a lightly doped region of the first conductivity type at the first main surface;
providing in the semiconductor substrate a plurality of trenches and a plurality of mesas with each mesa having an adjoining trench and a first extending portion extending from the first main surface toward the heavily doped region to a first depth position, at least one mesa having a first sidewall surface and a second sidewall surface, each of the plurality of trenches having a bottom;
doping with a dopant of a second conductivity type the first sidewall surface of the at least one mesa to form a first doped region of the second conductivity type;
doping with the dopant of the second conductivity type the second sidewall surface of the at least one mesa to form a second doped region of the second conductivity type;
doping with a dopant of the first conductivity type the first sidewall surface of the at least one mesa to provide a second doped region of the first conductivity type at the first sidewall, and doping with the dopant of the first conductivity type the second sidewall surface of the at least one mesa to provide a fourth doped region of the first conductivity type at the second sidewall;
lining at least the trenches adjacent to the at least one mesa with an oxide material; and
filling at least the trenches adjacent to the at least one mesa with one of a semi-insulating material and an insulating material.

2. The method according to claim 1, wherein the oxide lining is formed by one of low pressure (LP) chemical vapor deposition (CVD) Tetraethylorthosilicate (TEOS) and a spun-on-glass (SOG) deposition.

3. The method according to claim 1, further comprising:
forming a layer of undoped polysilicon, after the oxide lining step, over the trench bottoms and the mesas, each including the first and second sidewalls.

4. The method according to claim 1, wherein the step of filling the plurality of trenches with one of a semi-insulating material and an insulating material includes filling the plurality of trenches with at least one of undoped polysilicon, doped polysilicon, doped oxide, undoped oxide, silicon nitride and semi-insulating polycrystalline silicon (SIPOS).

5. The method according to claim 1, wherein the first sidewall surface has a first predetermined inclination maintained relative to the first main surface and the second sidewall surface has a second predetermined inclination maintained relative to the first main surface.

6. The method according to claim 1, wherein the first and second sidewall surfaces are generally perpendicular relative to the first main surface.

7. The method according to claim 1, wherein the plurality of trenches are formed utilizing one or more of plasma etching, reactive ion etching (RIE), sputter etching, vapor phase etching and chemical etching.

8. The method according to claim 1, wherein the implanting of the dopant of a second conductivity type into the first sidewall surface is performed at a first predetermined angle of implant.

9. The method according to claim 1, wherein the doping with the dopant of a second conductivity type into the second sidewall surface is performed at a second predetermined angle of implant.

10. The method according to claim 1, wherein the doping with the dopant of the first conductivity type into the first sidewall surface is performed at the first predetermined angle of implant.

11. The method according to claim 1, wherein the doping with the dopant of the first conductivity type into the second sidewall surface is performed at the second predetermined angle of implant.

12. The method according to claim 1, further comprising:
diffusing the dopants of the second conductivity type into the at least one mesa prior to doping with the dopants of the first conductivity type.

13. A semiconductor formed by the method of claim 1.

14. A method of manufacturing a semiconductor device comprising:
providing a semiconductor substrate having first and second main surfaces opposite to each other, the semiconductor substrate having a heavily doped region of a first conductivity type at the second main surface and having a lightly doped region of the first conductivity type at the first main surface;
providing in the semiconductor substrate a plurality of trenches and a plurality of mesas, with each mesa having an adjoining trench and a first extending portion extending from the first main surface toward the heavily doped region to a first depth position, at least one mesa having a first sidewall surface and a second sidewall surface, each of the plurality of trenches having a bottom;
doping with a dopant of the first conductivity type the first sidewall surface of the at least one mesa to form a first doped region of the first conductivity type;
doping with a dopant of the first conductivity type the second sidewall surface of the at least one mesa to form a second doped region of the first conductivity type;
doping with a dopant of the second conductivity type the first sidewall surface of the at least one mesa to provide a second doped region of the first conductivity type at the first sidewall, doping with the dopant of the second conductivity type the second sidewall of the at least one mesa;
lining at least the trenches adjacent to the at least one mesa with an oxide material; and
filling at least the trenches adjacent to the at least one mesa with one of a semi-insulating material and an insulating material.

15. The method according to claim 14, wherein the oxide lining is formed by one of low pressure (LP) chemical vapor deposition (CVD) Tetraethylorthosilicate (TEOS) and a spun-on-glass (SOG) deposition.

16. The method according to claim 14, further comprising:
forming a layer of undoped polysilicon, after the oxide lining step, over the trench bottoms and the mesas, each including the first and second sidewalls.

17. The method according to claim 14, wherein the step of filling the plurality of trenches with one of a semi-insulating material and an insulating material includes filling the plurality of trenches with at least one of undoped polysilicon, doped polysilicon, doped oxide, undoped oxide, silicon nitride and semi-insulating polycrystalline silicon (SIPOS).

18. The method according to claim 14, wherein the first sidewall surface has a first predetermined inclination maintained relative to the first main surface and the second sidewall surface has a second predetermined inclination maintained relative to the first main surface.

19. The method according to claim 14, wherein the first and second sidewall surfaces are generally perpendicular relative to the first main surface.

20. The method according to claim 14, wherein the plurality of trenches are formed utilizing one or more of plasma etching, reactive ion etching (RIE), sputter etching, vapor phase etching and chemical etching.

21. The method according to claim 14, wherein the doping with the dopant of a second conductivity type of the first sidewall surface is performed at a first predetermined angle of implant.

22. The method according to claim 14, wherein the doping with the dopant of a second conductivity type of the second sidewall surface is performed at a second predetermined angle of implant.

23. The method according to claim 14, wherein the doping with the dopant of the first conductivity type of the first sidewall surface is performed at the first predetermined angle of implant.

24. The method according to claim 14, wherein the doping with the dopant of the first conductivity type of the second sidewall surface is performed at the second predetermined angle of implant.

25. The method according to claim 14, further comprising:
diffusing the implanted dopants of the second conductivity type into the at least one mesa prior to implanting the dopants of the first conductivity type.

26. A semiconductor formed by the method of claim 14.
